(19) United States
(12) Patent Application Publication
(10) Pub. No.: US 2010/0007015 A1
(43) Pub. Date: Jan. 14, 2010

(54) INTEGRATED CIRCUIT DEVICE WITH IMPROVED UNDERFILL COVERAGE

(76) Inventor: Bernardo Gallegos, The Colony, TX (US)

Correspondence Address: TEXAS INSTRUMENTS INCORPORATED, P O BOX 655474, M/S 3999, DALLAS, TX, 75265, US

(21) Appl. No.: 12/171,759

(22) Filed: Jul. 11, 2008

(51) Int. Cl. H01L 23/488; H01L 21/56

(52) U.S. Cl. 257/737; 438/127; 257/E23.023; 257/E21.502

(57) ABSTRACT

An integrated circuit device (300) includes a functional integrated circuit (IC) die (310) having a top IC surface with IC non-contact regions (313) and a plurality of electrically conductive bump pads (311, 312, 313) at pad locations. In the IC (310), at least one of the bump pads (311, 312, 313) extends outward from beyond the IC non-contact regions (313). The integrated circuit device (300) can also include a workpiece (305) having a top workpiece surface comprising at least one die attach area (319) for attaching the IC die (310). The die attach area (319) can include non-contact regions (316) and a plurality of electrically conductive contact pads (317) recessed relative to the non-contact regions (316), where the contact pads (317) face the top IC surface and match the pad locations (312). In the die attach area (319), at least one of the contact pads (317) includes electrically conductive pedestal features (321) extending towards the top IC surface, where the extending bump pads (311) physically contact one of the pedestal features (321) and electrically connect the IC die (310) to the workpiece (305). In the integrated circuit device (300), the pedestal features (321) increase a gap between the IC (310) and the workpiece top surfaces to be filled with an underfill dielectric material (332).

### FIELD OF THE INVENTION

The present invention is related in general to the field of semiconductor devices and processes, and more specifically to integrated circuit devices having improved underfill between an integrated circuit die and a workpiece surface.

### BACKGROUND

The flip chip package is an advanced packaging technique for connecting an integrated circuit (IC) die to a workpiece (e.g. printed circuit board (PCB)). During the IC die manufacturing process, a plurality of bump pads are formed to electrically contact the IC die, commonly using under bump metallurgy (UBM). During the packaging process, the IC die is turned upside down to connect to the IC die to a set of metal bond pads on the workpiece matching the bumps of the IC die, electrically contacting the IC die and the workpiece.

The workpiece is commonly a dielectric substrate where the metal bond pads are accessible at a first surface. The workpiece also generally includes metal interconnect layers having respectively a plurality of metal conductive wires located therein, electrically connected by a plurality of vias. In some workpieces, the metal bond pads can be formed in a surface metal interconnect layer. In the case of surface interconnect layers formed using reactive materials, a passivation layer can be provided over the surface interconnect layer, commonly patterned to expose only the bond pad portions formed in the surface interconnect layer. The flipped IC die is typically bonded to the workpiece by soldering of the metal bond pads on the workpiece and the bump pads on the IC die surface. Then an underfill layer is formed between the IC die and the workpiece. Underfill generally comprises a polymeric material, such as a silica-filled epoxy resin. The function of the underfill is to reduce the stresses in the solder joints caused by a coefficient of thermal expansion (CTE) mismatch.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

A properly formed underfill between an IC die and a workpiece is typically a requirement for reducing the likelihood of interfacial failure in the flip-chip packaging system. That is, the underfill material typically needs to substantially fill in the entire in the space between the IC die and the workpiece (e.g. PCB) surface to provide a reliable flip chip package. Particularly in the case of Au—Au bonding technology, a narrow gap between the bottom of the IC die and top surface of workpiece can result after bonding. Such narrow gaps increase the challenge of the underfill flow underneath the IC die, generally producing underfill voids in tight areas concentrated mostly in the center of the package under the die, leading to reliability failures. One solution can be to remove the solder mask layer from the workpiece top side surface in areas under the IC die since this increases the height of the gap between the IC die and the workpiece.

However, removal of the solder mask layer is not always desirable and can cause reliability degradation due to delamination between the workpiece and the underfill or poor electrical contact between an IC die and the workpiece. For example, a solder mask layer typically functions as an adhesion promoter, as adhesion between underfill materials and the solder mask layer is typically greater than that between underfill layers and typical workpiece materials. The solder mask provides passivation of exposed workpiece metals and removing the protective solder mask layer can lead to oxidation of exposed oxidizable metals, such as coppers which can other wise result in poor adhesion between the underfill and the workpiece. The solder mask layer can also control controlling reflow and guide additional plating of contact pads. That is, the solder mask can additional plating of workpiecce contact pads and keep any reflow solder and/or underfill in place.

To avoid removal of the solder mask layer from the workpiece, embodiments of the present invention provide for forming structures which extend upward from the metal contact pads on the workpiece surface, hereinafter referred to as “pedestal structures”. The pedestal structures can be formed in areas of the metal contact pads of the workpiece surface corresponding to the areas of IC die having bump pads. As a result, portions of these bumps are instead bonded to and/or collapsed on the elevated pedestal structures, resulting in an increased final height for the bump pads and the contact pads on the workpiece. Consequently, an increased gap between the IC die and the workpiece is provided which reduces the challenge of underfilling this gap between the IC die and the workpiece. The increased gap generally reduces the amount of underfill voids in tight areas including areas near the center of the IC die area, leading to improved reliability.

### BRIEF DESCRIPTION OF THE DRAWINGS

FIGS. 1A and 1B show cross-sections of portions of a IC die and a workpiece, prior to reflow bonding, excluding and including, respectively, a pedestal according to an embodiment of the present invention.

FIGS. 1C and 1D show cross-sections of portions of an IC die and a workpiece, subsequent to reflow bonding, excluding and including, respectively, a pedestal according to an embodiment of the present invention.

FIG. 2 shows an exemplary method for forming an integrated circuit device according to an embodiment of the present invention.

FIG. 3 shows a cross-section of an integrated circuit device according to an embodiment of the present invention.

FIG. 4 shows an exploded view of an exemplary multi-chip stacked package on package (POP) packaging system 400, according to another embodiment of the present invention.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Embodiments of the present invention provide for forming pedestal structures, where each of the pedestal structures extends upwards from one or more of the contact pad areas. The pedestal structures are used to improve underfill of the gap between the workpiece surface and an attached IC die comprising a flip-chip IC by increasing the gap height. A workpiece, as used herein include printed circuit boards, integrated circuit packages, or other IC dies. Thus, the pedestal structures allow the solder mask to be retained under the IC die. Retaining the solder mask layer under the IC die is advantageous to prevent an oxidizable metal (e.g. Cu) features of the workpiece from oxidizing due to unpredictable environment conditions, to promote adhesion, or to control plating and/or reflow. The increased gap height provided by the pedestal structures has been found by the present Inventor to reduce underfill voids in various areas between the IC die and the workpiece, including areas near the center of the IC die, leading to improved reliability. Flip-chip (FC) methods according to embodiments of the invention are described herein for assembling an IC die with metal bump pads at pad locations to a workpiece having a surface including contact pads with pedestal structures matching the pad locations.

In the various embodiments of the present invention, thermal (reflow) bonding methods, ultrasonic bonding methods, or any combination thereof can be used for electrically connecting the IC die and the workpiece. In the case of ultrasonic methods, the bump pads being bonded are typically not significantly deformed. That is, ultrasonic energy is used to remove impurities and oxidation from the interface between bump pad and contact pad or pedestal without significant deformation of the bump pad. Accordingly, in embodiments of the present invention utilizing ultrasonic bonding, bonding of the bump pads to the elevated pedestal therefore results in the gap between the IC die and the workpiece being effectively increased by the height of the pedestal. In some embodiments, the bump pads can bond to a bonding layer of the same or a different composition, deposited on the pedestal structures and the contact pads. Although the bonding layer and the bump pads can comprise dissimilar metals or metal alloys, one of ordinary skill in the art will recognize that using a same metal or metal alloys provides improved electrical characteristics. For example, in flip-chip technologies, a gold to gold bond (Au—Au bond) is commonly used to provide good electrical conductivity. As used herein, any Au comprising stud to Au comprising surface interconnection is referred to as Au—Au bond.

In the case of reflow or thermal bonding methods, utilizing a pedestal in accordance with the various embodiments of the present invention also results in an increased gap height. In particular, such embodiments utilize non-reflow metals for the pedestal and contact pad and reflow metals for any solder bumps formed on the bump pads and any bonding layers formed on the pedestal structures or contact pads. As used herein, the term “reflow metals” refers to metals or metal alloys which soften at temperatures below 320° C. Examples are solders made of tin or various tin alloys (containing silver, copper bismuth, and lead). In contrast, the term “non-reflow metals” refers to metals or metal alloys which soften at temperatures above 800° C. Examples are silver, gold, and copper.

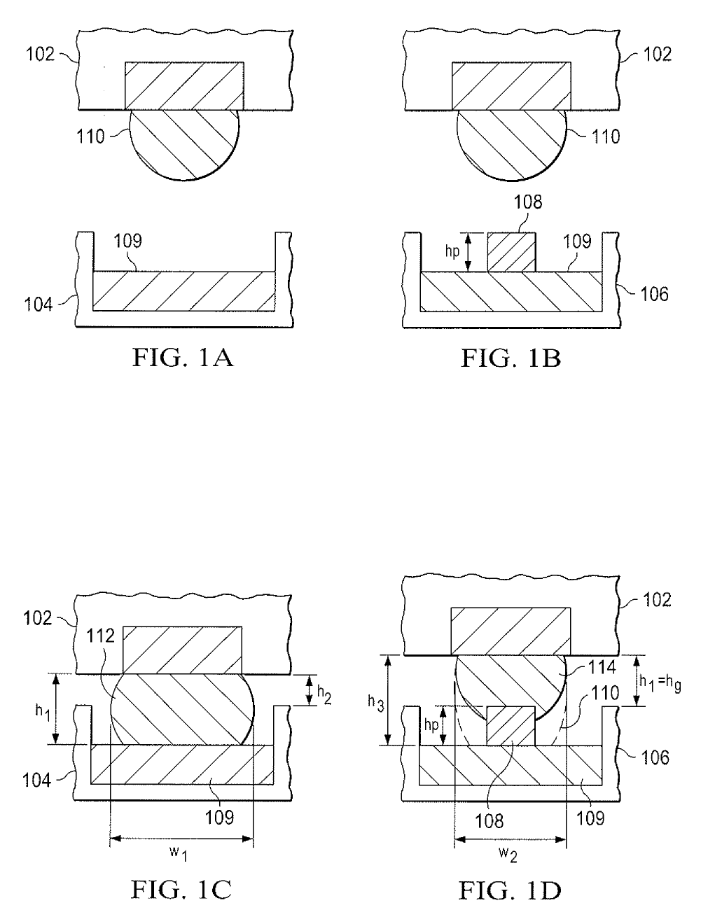

In the case of reflow or thermal bonding, the present Inventor notes that although IC solder bumps comprising reflow metals typically conform to the underlying structures in the workpiece during reflow, the height and thickness of the post-reflow bump is still determined primarily by the features in the workpiece having the greatest height. This is conceptually illustrated in FIGS. 1A-1D, described below.

FIGS. 1A and 1B show portions of a flip-chip IC die 102 prior to reflow or thermal bonding with a conventional workpiece 104 and with a workpiece 106 including a pedestal pad 108 in contact pad regions 109 according to the various embodiments of the present invention, respectively. As shown in FIGS. 1A and 1B, prior to bonding with either of workpieces 104 or 106, the height of solder bump 110 in flip-chip IC die 102 is identical for either workpiece. However, FIGS. 1C and 1D show post-thermal bonding results for the a workpiece excluding and including, respectively, a pedestal structure in accordance with an embodiment of the present invention. As shown in FIGS. 1C and 1D, once the workpieces 104 and 106 are thermally bonded with a IC die 102, the heights of the resulting solder bumps 112 and 114, respectively, can vary. For the conventional workpiece 104, the reflow of solder bump 110 when bonding of the IC die 102 and the workpiece 104 generally results in a flattened solder bump 112 having a height h₁ sandwiched between the contact pad regions 109 of the workpiece 104 and the IC die 102, as shown in FIG. 1C. The final value of height h, can vary depending on the reflow conditions, including the temperature profile during the thermal bonding process, the melting or softening point of materials comprising the solder bump 110, and the pressure applied between the workpiece 106 and the IC die 102. As one of ordinary skill in the art will recognize, one set of thermal bonding conditions consistently results in a minimum gap between the two closest portions of the bonded IC and workpiece contacted by the solder bump. However, the actual minimum gap between an IC and a workpiece can be less than this height. For example, in the case of recessed contact pads, as shown in FIG. 1C, the actual gap h₂ can be less than the resulting solder bump height h₁. This smaller gap can cause reliability problems when h₂ is less than a minimum height necessary for flowing an adequate flow of underfill material between the IC die 102 and the workpiece 104. An inadequate flow of underfill material through the gap between the IC die 102 and the workpiece can result in voids, poor adhesion, and possible delamination. In the various embodiments of the present invention, the gap height provided can vary according to the type of underfill material being used. For example, some underfill materials can adequately flow through a gap of Sum or less. However, other materials can require a larger gap, such as between Sum and 25 to allow proper flow of the underfill material.

Accordingly, because the a minimum height is generally maintained under the same thermal bonding conditions, some embodiments of the present invention use this minimum resulting height to increase the overall height of the minimum gap h₂ between a IC die and a workpiece. That is, if the reflow of solder bump 110 and bonding of the IC die 102 and workpiece 106 is achieved using the same process conditions as in FIG. 1C, a larger gap can be obtained if a pedestal 108 is incorporated into the workpiece 106. As shown in FIG. 1D, after thermal bonding, the height h₁ is still maintained between the top of the pedestal 108 and the IC die 102. This is a result of the top of the pedestal 108 being elevated with respect to the contact pad 109. Accordingly, a total height between the contact pad 109 and the IC die 102 is increased to hₚ+h₁=h₃. As a result, the increased total height h₃ translates to an increased gap height h_{g} as compared to the gap h₂ in FIG. 1C. In the exemplary embodiment in FIG. 1D, in which the contact pad recess and the height of pedestal 109 are the same, h_{g}=h₁. However, the invention is not limited in this regard. One of ordinary skill in the art will recognize that a pedestal of any height or shape can be used in the various embodiments of the present invention. For example, square or round pedestals can be used. However, the invention is not limited in this regard. Similarly, the dimensions of the contact pads, the bump pads, solder bumps, and recess depths can also vary in the various embodiments of the present invention.

Furthermore, because reflow does not typically completely collapse the solder bump 110, the resulting solder bump 114, as shown in FIG. 1D, can a width w₂ that is the same or different than a width w₁ of the resulting solder bump 112 for the conventional workpiece, also as shown in FIG. 1D. Thus, in cases where w₂ is less than w₁, underfill flow through the gap after thermal bonding is further improved by the increased spacing between the resulting solder bump 114 and adjacent portions of the workpiece 106 and/or the IC die 102. Additional underflow material flow Improvement can also be provided by increasing the height of the pedestal hₚ. Therefore, even if the width w₂ is not less than w₁, the space added by elevating the bump 114 improves the flow of the underfill material.

Additionally, the pedestal 108 can improve reliability in connecting the solder ball. For example, in cases where the solder ball 114 extends down the sides of the pedestal 208 into regions 116, the solder ball 114 can contact the pedestal 108 over a greater surface area that without the pedestal 108. Accordingly, a stronger bond is formed, reducing the likelihood of delamination or other reliability failures.

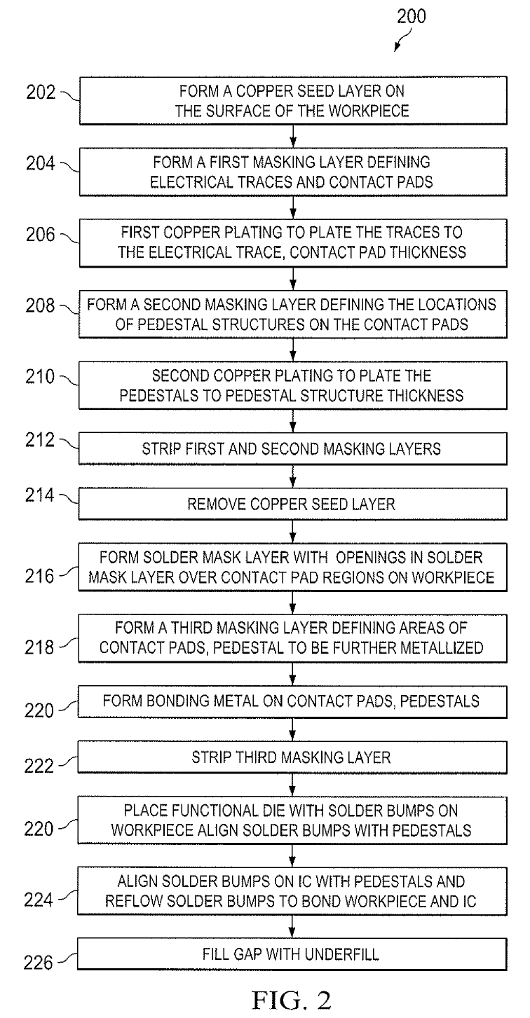

FIG. 2 is a flow chart for an exemplary assembly method for an integrated circuit device 200 according to an embodiment of the invention. The processes described below can generally be performed with standard equipment and materials already used in the semiconductor industry. For example, in step 202, a blanket copper seed layer can be deposited on an upper surface of the workpiece. Afterwards, in step 204, a masking material pattern is applied for defining the location of electrical traces and contact pads on the surface of the workpiece. The masking layer can be photoresist or another suitable masking material. Step 206 comprises forming a metal comprising layer. In the exemplary embodiment in method 200, step 206 can comprise plating, such as Cu plating. The metal comprising layer is formed to generally provide a specified thickness range.

Once the contact pads have been defined and formed in steps 204 and 206, a second masking material pattern is formed with openings over on the contact pads to define locations of pedestal structures in the workpiece in step 208. This is followed by step 210, in which a second metal comprising layer is formed on the first metal comprising layer. The second metal comprising layer is forms pedestal structures on the underlying contact pads. In the exemplary embodiment in method 200, step 210 can comprise plating, such as Cu plating. The thickness of the second layer can vary, depending on several factors. For example, in the case of Cu plating, the thickness can vary between 3 um and 20 um. However, if a fine pitch is used for the pads, a thinner thickness of the second metal layer can be used to allow proper formation of the pedestals. In such cases, the second metal layer thickness can be limited to, for example, between 3 um and 8 um. However, the invention is not limited to using contact pads and pedestal structures comprising the same materials. In some embodiments of the present invention, contact pads and pedestal structures can comprise different materials. However, in the case of thermal or reflow bonding, the pedestal can be formed from non-reflow metal comprising materials to prevent its deformation, as previously described.

Once the pedestal structures are formed in step 210, the first and second masking materials are stripped off in step 212. A suitable process, such as flash etching, can be performed in step 214 to remove any remaining portions of the copper seed layer underneath the masking layer (e.g. photoresist).

Afterwards in step 216, the solder mask layer is formed. In particular, step 216 comprises forming a dielectric solder mask layer on the workpiece and having openings over at least the contact pad regions. In some embodiments, a surface preparation clean can also be included in preparation or the workpiece prior to the solder mask process. The solder mask layer can be applied either by a liquid resist or a dry film solder mask layer. An example of a liquid resist is Taiyo AUS320 and example of dry film mask is Taiyo AUS410 (TAIYO AMERICA, INC., Carson City, Nev., a manufacturing subsidiary of FAIYO INK MFG. CO., LTD. (Japan).

In embodiments where a bonding layer is formed on the pedestal structures and the contact pads, step 218 can include applying a masking material (e.g. photoresist) to block areas under the die, except where the contact pads are to be formed, including both periphery and core pads. Afterwards, in step 220 a bonding layer can be formed in the contact pad area to promote bonding. In the case of ultrasonic the bonding layer and the solder bumps on the IC can comprise substantially similar materials, as previously described, to provide a seamless joint. In the case of thermal or reflow bonding, the bonding layer can comprise a reflow metal. Subsequently, in step 222, the masking material can be removed (e.g. resist strip).

After the workpiece has been prepared in step 202-222. The IC die is then attached and electrically connected to the workpiece in step 224 by bonding the contact pads and/or pedestal structures to the bump pads and/solder bumps. Thermal bonding, ultrasonic bonding, or any combination thereof can be used for such bonding, as previously described. Once the IC die and the workpiece are attached and electrically connect in step 224, in step 226, the gap between the IC die and the workpiece is filled with an underfill material, such as a resin-based dielectric material. Depending on the package type, a subsequent molding step may or may not be performed. For example, certain package-on-package (POP) packages may not have molding, but chip scale packages (CSP) will generally include the mold compound.

Although the exemplary method 200 is described with respect to a workpiece including copper-comprising contact pads and pedestal structures, one of ordinary skill in the art will recognize that workpieces using other type of interconnect layer materials can also be used. For example, rather than the additive processes of copper seed deposition and copper plating required for copper comprising interconnects, subtractive processes, such as those used for depositing and etching aluminum comprising interconnects can be used in some embodiments of the present invention.

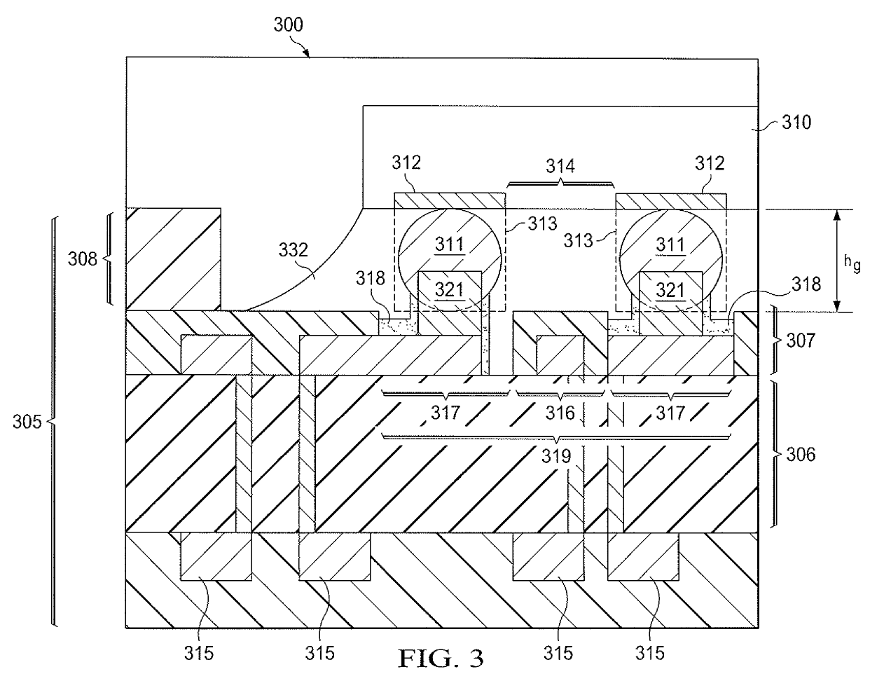

FIG. 3 shows portion of a cross-section of an exemplary integrated circuit device 300 according to an embodiment of the invention. Device 300 comprises a workpiece 305 comprising a printed circuit board (PCB) bonded to an IC die 310 having solder bumps 311 attached to bump pads 312 separated by non-contact regions 314 in the IC die 310. In one embodiment, the solder bumps 311 comprise electrically conductive metals or alloys thereof, such as metal alloys including Cu, Ni, Au, Pd, or Ag. In some embodiments, extended bump pads 313 can be used alternatively or in combination with solder bumps 311, where the bump pads 313 can extend downward from the surface of the IC die 310.

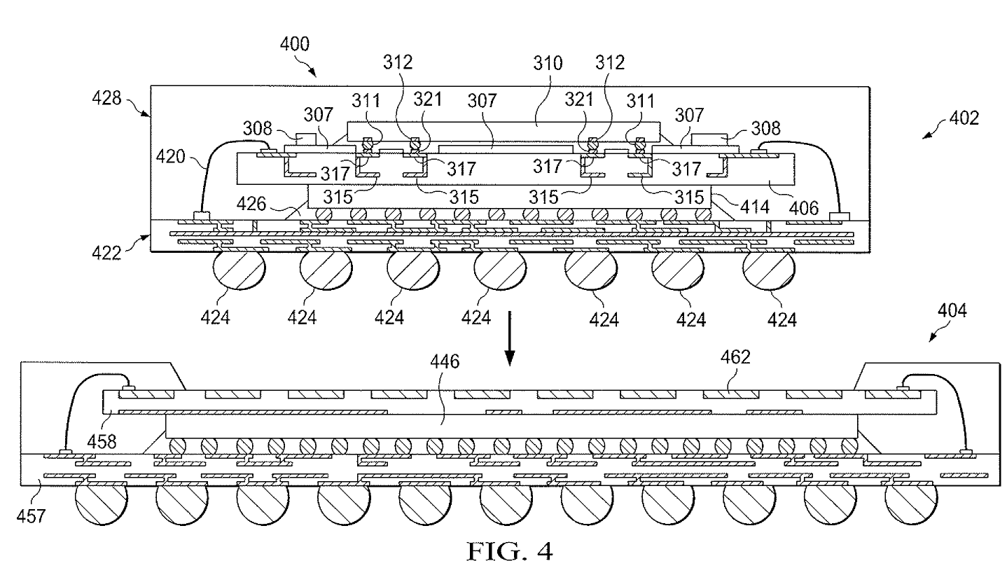

Although the workpiece 305 is shown in FIG. 3 as a multiple layer circuit board, the workpiece 305 can comprise a single-layer circuit board. In another embodiment, the workpiece 305 can also be an IC die. Moreover, although only one IC die is shown, embodiments of the invention can include multiple IC die stacked horizontally and/or vertically, such as the POP package arrangement shown in FIG. 4 described below. The workpiece 305 generally comprises a dielectric core layer 306, such as FR4. Workpiece 305 also includes solder mask layer 307 which is on the topside and bottomside of core 306, and optional second solder mask layer 308 which acts as a dam or wall to help keep the underfill material 332 within and generally under the bumped die 310. This second solder mask layer 308 also prevents the underfill 332 from spreading to the periphery of the package, such as to a memory device (not shown) mounted laterally on the same workpiece 305. Solder mask layer 307 is excluded from areas of the workpiece surface corresponding to areas beneath the bumped die 310. Workpiece further includes metal comprising regions 315, such as copper regions. The workpiece 305 includes contact pad regions 317 of the metal comprising regions 315 separated by non-contact regions 316.

Underfill material 332 fills the space between the bumped IC die 310 and a die attach region 319 of the workpiece 305. As described above, in the various embodiments of the present invention the underfill process is improved by adding pedestal portions 321 onto the surface of contact pad regions 317 in workpiece areas under the die 3 10. As previously described, the pedestal structures 321 provides an increased gap height h, for promoting am improved fill of the gap by the underfill 332. Accordingly, voids in the underfill 332 can be reduced without requiring removal of the solder mask layer 307 protecting the metal regions 315 from oxidation due to unpredictable environment conditions.

In some embodiments, such as in FIG. 3, the contact pad regions 317 and the pedestal structures 321 can have a bonding layer 318 formed thereon. As previously described, the composition of the bonding layer can be selected to promote bonding during either ultrasonic or thermal bonding processes.

FIG. 4 shows an exploded view of an exemplary multi-chip stacked package on package (POP) packaging system 400, according to another embodiment of the present invention. System 400 comprises a top package 402 and a bottom package 404. Top package 402 comprises a pair of IC die 414 and 310, where IC die 310 is in a flip-chip configuration on top of bottom package 404.

Workpiece 306, previously described in FIG. 3, is shown as a PCB substrate in FIG. 4. The surface of workpiece 306 includes metal comprising regions 315, such as copper regions, having adhesion pedestal structures 321 thereon in the region under die 310. IC die 310 is mounted in a flip-chip configuration, contacting a plurality of terminals on the upper surface of the workpiece 306. The terminals can be connected via bonding wires 420 to terminals on the upper surface of lower workpiece 422 shown as a multi-layer PCB in FIG. 4. Workpiece 422 has electrical connections to leads 424. Underfill 426 fills underneath IC die 414. Molding 428 is used to encapsulate dies 310 and 414.

Bottom package 404 comprises IC die 446 which is interposed between workpiece 457 which is shown comprising a multi-layer PCB and upper workpiece 458 having surface pads 462. Leads 424 from top package 402 electrically connect top package 402 to pads 462 of bottom package 404.

These are but a few examples. Accordingly, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has” “with”, or variants thereof are used in either the detailed description and/or the claims, such terms are intended to be inclusive in a manner similar to the term “comprising.”

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

1. An integrated circuit device, comprising:
a functional integrated circuit (IC) die having a top IC surface comprising IC non-contact regions and a plurality of electrically conductive bump pads at pad locations including at least one extending bump pad extending outward from said top IC surface beyond said IC non-contact regions;
a workpiece having a top workpiece surface comprising at least one die attach area for attaching said IC die, said die attach area comprising workpiece non-contact regions and a plurality of electrically conductive contact pads recessed relative to said workpiece non-contact regions, said contact pads facing said top IC surface and matching said pad locations, at least one of said contact pads being a pedestal contact pad comprising one or more electrically conductive pedestal features extending outward from said top workpiece surface towards said top IC surface, and said extending bump pad physically contacting said pedestal features to electrically connect said functional IC die to said workpiece, said pedestal features increasing a gap between said IC and said workpiece top surfaces; and
an underfill dielectric material filling said gap.

2. The integrated circuit device of claim 1, wherein said contact pads are recessed a contact depth, and wherein a height of said pedestal features is greater than said contact depth.

3. The integrated circuit device of claim 1, wherein an area of said pedestal features is less than an area of said pedestal contact pad.

4. The integrated circuit device of claim 3, wherein said pedestal features extend from a central region of said pedestal pad.

5. The integrated circuit of claim 1, said workpiece further comprising a bonding layer disposed on said contact pads.

6. The integrated circuit of claim 1, wherein a distal portion of said extending bump pad further comprises a solder bump.

7. The integrated circuit of claim 6, said workpiece further comprising a bonding layer disposed on said contact pads, wherein said bonding layer and said solder bumps comprise one or more reflow metals, and wherein said contact pads and said pedestal features comprise one or more non-reflow metals.

8-14. (canceled)

15. An integrated circuit device, comprising:
a functional integrated circuit (IC) die having a top IC surface comprising IC non-contact regions and a plurality of electrically conductive bump pads at pad locations including an extending bump pad extending outward from said top IC surface beyond said IC non-contact regions;
a workpiece having a top workpiece surface comprising at least one die attach area for attaching said IC die, said die attach area comprising first solder mask regions and a plurality of electrically conductive contact pads recessed relative to said solder mask regions, and said workpiece further comprising a second solder mask region surrounding said die attach area, wherein said contact pads face said top IC surface and match said pad locations, wherein at least one of said contact pads being a pedestal pad comprises at one or more electrically conductive pedestal features extending outward from said top workpiece surface towards said top IC surface to a height above said second solder mask regions, and wherein said extending bump pad physically contacting one of said pedestal features to electrically connect said functional IC and said workpiece, said pedestal features increasing a gap between said IC and said workpiece top surfaces; and
an underfill dielectric material filling said gap.

16. The integrated circuit device of claim 15, wherein an area of said pedestal features is less than an area of said pedestal pad.

17. The integrated circuit device of claim 16, wherein said pedestal features extend from a central region of said pedestal pad.

18. The integrated circuit of claim 15, said workpiece further comprising a bonding layer disposed on said contact pads.

19. The integrated circuit of claim 15, wherein a distal portion of said extending bump pad further comprises a solder bump.

20. The integrated circuit of claim 19, said workpiece further comprising a bonding layer disposed on said contact pads, wherein said bonding layer and said solder bump comprise one or more reflow metals, and wherein said contact pads and said pedestal features comprise one or more non-reflow metals.
